(19) United States
(12) Patent Application Publication
(10) Pub. No.: US 2013/0311120 A1
(43) Pub. Date: Nov. 21, 2013

(54) BATTERY VOLTAGE DETECTION METHOD AND APPARATUS

(71) Applicant: HON HAI PRECISION INDUSTRY CO., LTD., New Taipei (TW)

(72) Inventors: TING-YANG LIN, New Taipei (TW); I-CHAN HU, New Taipei (TW); CHENG-TA HU, New Taipei (TW)

(73) Assignee: HON HAI PRECISION INDUSTRY CO., LTD., New Taipei (TW)

(21) Appl. No.: 13/798,773

(22) Filed: Mar. 13, 2013

(30) Foreign Application Priority Data
May 18, 2012 (TW) 101117923

(51) Int. Cl. G01R 19/00

(52) U.S. Cl. CPC G01R 19/0084
USPC 702/64

(57) ABSTRACT

An exemplary apparatus for detecting a voltage of a battery on a motherboard includes an embedded controller, a first resistor, and a second resistor. The embedded controller includes an analog to digital (A/D) conversion terminal The A/D conversion terminal is electrically connected to a voltage output terminal of the battery via the first resistor. The A/D conversion terminal is grounded via the second resistor. The A/D conversion terminal detects a voltage value of a connection point between the first resistor and the second resistor. The embedded controller calculates the potential of the battery to determine whether the battery is installed on the motherboard according to the voltage value.

### CROSS-REFERENCE TO RELATED APPLICATION

The present application is related to co-pending U.S. Patent Application entitled “METHOD AND APPARATUS FOR TESTING CIRCUIT BOARD,” Attorney Docket Number US44544, simultaneously filed with the present application.

### BACKGROUND

1. Technical Field

The present disclosure relates to a method and apparatus for detecting batteries on a circuit board and power levels of the batteries.

2. Description of Related Art

In computer systems, the memory and real-time clock are generally powered by RTC (real-time clock) batteries. Firstly, the RTC batteries may not be installed on motherboards during the assembly by mistake. Secondly, the life of the RTC batteries depends on the length of time that the computer system is powered off. Users may not know that the charge of the RTC battery is exhausted and needs to be replaced.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a circuit diagram of an embodiment of an apparatus for detecting voltage of a battery.

FIG. 2 is a flow chart of a method for detecting voltage of the battery.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

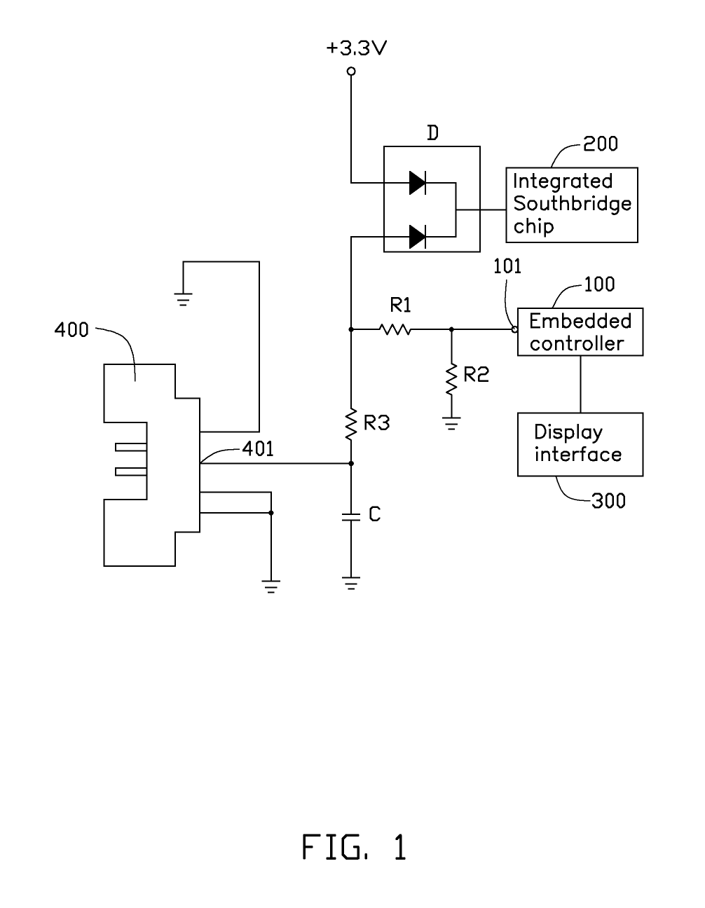

FIG. 1 is a schematic view of an embodiment of an apparatus for detecting rest voltage of a battery 400 on a motherboard, in accordance with one embodiment.

The apparatus includes an embedded controller 100, a first resistor R1, a second resistor R2, a third resistor R3, a capacitor C, a Schottky diode D, an integrated Southbridge chip 200, and a display interface 300 electrically connected to the embedded controller 100.

The embedded controller 100 includes an analog to digital (A/D) conversion terminal 101. The A/D conversion terminal 101 is grounded via the first resistor R1, the third resistor R3, and the capacitor C in series. A connection point between the third resistor R3 and the capacitor C is electrically connected to a voltage output terminal 401 of the battery 400. The A/D conversion terminal 101 is grounded via the second resistor R2. The A/D conversion terminal 101 detects a voltage value of a connection point between the first resistor R1 and the second resistor R2. The embedded controller 100 detects and calculates a voltage of the battery 400 to determine whether the battery 400 is installed on the motherboard. The embedded controller 100 stores a rated voltage and a final voltage. In one embodiments, the rated voltage is +3V, the final voltage is +2V. In other embodiments, any of various other kinds of circuit boards take the place of the motherboard.

The Schottky diode D includes a first anode, a second anode, and a cathode. The A/D conversion terminal 101 is electrically connected to the first anode of the Schottky diode D via the first resistor R1. The second anode of the Schottky diode D receives a direct current (DC) voltage. The cathode of the Schottky diode D is electrically connected to the integrated Southbridge chip 200. In one embodiment, the DC voltage is +3.3V. When the motherboard is powered on, the +3.3V DC voltage is provided to the integrated Southbridge chip 200 via the second anode of the Schottky diode D. The integrated Southbridge chip 200 does not use or consume the voltage of the battery 400. When the motherboard is powered off, the battery 400 provides power to the integrated Southbridge chip 200 via the third resistor R3 and the second anode of the Schottky diode D.

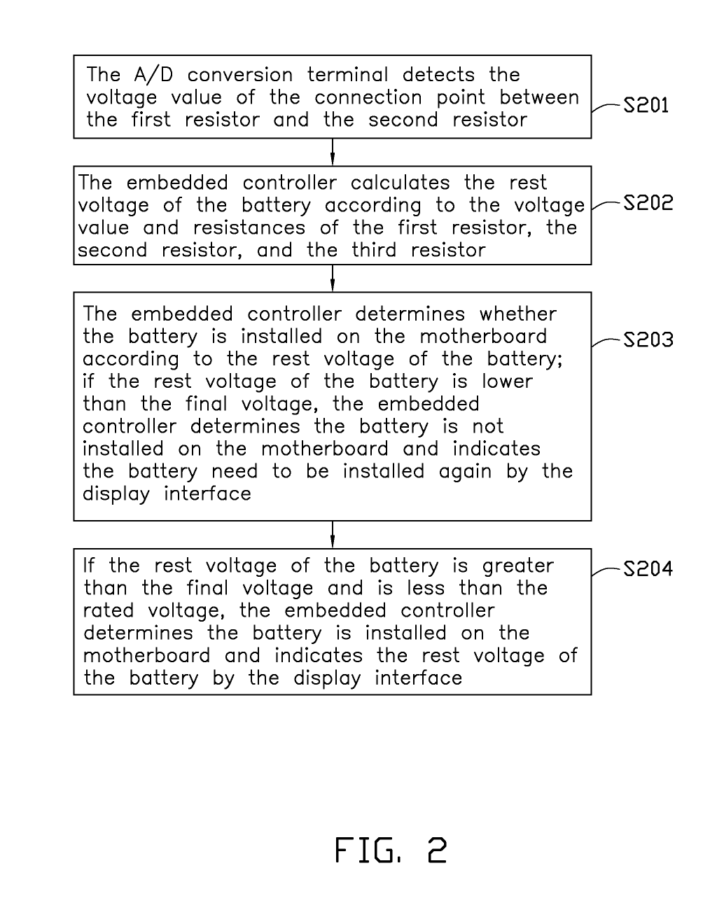

FIG. 2 illustrates a flow chart of an embodiment of a method for detecting voltage of the battery 400, in accordance with one embodiment. Depending on the embodiment, certain steps described below may be removed, while others may be added, and the sequence of the steps may be altered. In one embodiment, the method for detecting utilizing the above-described apparatus includes the following steps:

S201: the A/D conversion terminal 101 detects the voltage value of the connection point between the first resistor R1 and the second resistor R2.

S202: the embedded controller 100 calculates the voltage of the battery 400 according to the voltage value and resistances of the first resistor R1, the second resistor R2, and the third resistor R3.

S203: the embedded controller 100 determines whether a battery is installed on the motherboard according to the voltage of the battery 400; if a detected voltage is lower than the final voltage, the embedded controller 100 determines that the battery 400 is not installed on the motherboard and indicates accordingly (that the battery 400 needs to be installed or replaced), by the display interface 300.

S204: if the voltage of the battery 400 is greater than the final voltage but is less than the rated voltage, the embedded controller 100 determines that the battery 400 is installed on the motherboard and indicates the voltage of the battery 400 on the display interface 300.

For example, the embedded controller 100 calculates the current of the second resistor R2 by using the voltage value of the connection point between the first resistor R1 and the second resistor R2, divided by the resistance of the second resistor R2. The embedded controller 100 calculates the voltage of the battery 400 by using the current of the second resistor R2 multiplied by the sum of the resistances of the first resistor R1, the second resistor R2, and the third resistor R3.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An apparatus for detecting rest voltage of a battery on a motherboard comprising:
an embedded controller, a first resistor, and a second resistor; wherein the embedded controller comprises an analog to digital (A/D) conversion terminal; the A/D conversion terminal is electrically connected to a voltage output terminal of the battery via the first resistor; the A/D conversion terminal is grounded via the second resistor; the A/D conversion terminal detects a voltage value of a connection point between the first resistor and the second resistor; and the embedded controller calculates a rest voltage value of the battery and determines whether the battery is installed on the motherboard according to the rest voltage value.

2. The apparatus of claim 1, further comprising a Schottky diode and an integrated Southbridge chip; the Schottky diode comprises a first anode, a second anode, and a cathode; the A/D conversion terminal is electrically connected to the first anode of the Schottky diode via the first resistor; the second anode of the Schottky diode receives a Direct Current (DC) voltage; and the cathode of the Schottky diode is electrically connected to the integrated Southbridge chip.

3. The apparatus of claim 2, further comprising a third resistor and a capacitor; the A/D conversion terminal is grounded via the first resistor, the third resistor and the capacitor in series; and a connection point between the third resistor and the capacitor is electrically connected to the voltage output terminal of the battery.

4. The apparatus of claim 3, further comprising a display interface electrically connected to the embedded controller; and the display interface displays the rest voltage value of the battery and indicates whether the battery is installed on the motherboard.

5. The apparatus of claim 4, wherein the DC voltage is +3.3V.

6. A method for detecting rest voltage of a battery on a motherboard, the method comprising:
detecting a voltage value of a connection point between a first resistor and a second resistor by an analog to digital (A/D) conversion terminal on an embedded controller;
wherein embedded controller stores a rated voltage value and a final voltage value;
calculating a rest voltage value of the battery according to the voltage value and resistances of the first resistor and the second resistor by the embedded controller; and
determining whether the battery is installed on the motherboard according to the rest voltage value of the battery by the embedded controller;
if the rest voltage value of the battery is lower than the final voltage value, the embedded controller determines the battery is not installed on the motherboard, and indicates the battery need to be installed by a display interface;
if the rest voltage value of the battery is greater than the final voltage value and is less than the rated voltage value, the embedded controller determines the battery is installed on the motherboard, and indicates the rest voltage value of the battery by the display interface.

7. The method of claim 6, wherein the A/D conversion terminal is electrically connected to a voltage output terminal of the battery via the first resistor; and the A/D conversion terminal is grounded via the second resistor.

8. The method of claim 7, wherein the A/D conversion terminal is electrically connected to a first anode of a Schottky diode via the first resistor; a second anode of the Schottky diode receives a Direct Current (DC) voltage; and a cathode of the Schottky diode is electrically connected to an integrated Southbridge chip.

9. The method of claim 8, wherein the DC voltage is +3.3V.
